(19) United States
(12) Patent Application Publication
(10) Pub. No.: US 2010/0207177 A1
(43) Pub. Date: Aug. 19, 2010

(54) METHOD FOR PRODUCING A COPPER CONTACT

(75) Inventors: Chung-Shi Liu, Tervuren (BE); Gerald Beyer, Lauven (BE); Steven Demuynck, Aarschot (BE); Zsolt Tokei, Leuven (BE); Roger Palmans, Riemst (BE); Chao Zhao, Kessel-Io (BE); Chen-Hua Yu, Hsin-Chu (TW)

Correspondence Address: KNOBBE MARTENS OLSON & BEAR LLP, 2040 MAIN STREET, FOURTEENTH FLOOR, IRVINE, CA, 92614, US

(73) Assignees: IMEC, Leuven (BE); Taiwan Semiconductor Manufacturing Company, Ltd. (TSMC), HsinChu (TW)

(21) Appl. No.: 12/641,945

(22) Filed: Dec. 18, 2009

Related U.S. Application Data
(63) Continuation of application No. PCT/EP2008/058346, filed on Jun. 29, 2008.

(30) Foreign Application Priority Data
Jun. 29, 2007 (EP) EP 07111392.2

(51) Int. Cl. H01L 23/532; H01L 21/768; H01L 29/78; H01L 23/522

(52) U.S. Cl. 257/288; 438/627; 257/751; 257/E21.584; 257/E29.255; 257/E23.161; 257/E23.145

(57) ABSTRACT

A method for producing a contact through the pre-metal dielectric (PMD) layer of an integrated circuit, between the front end of line and the back end of line, and the device produced thereby are disclosed. The PMD layer includes oxygen. In one aspect, the method includes producing a hole in the PMD, depositing a conductive barrier layer at the bottom of the hole, depositing a CuMn alloy on the bottom and side walls of the hole, filling the remaining portion of the hole with Cu. The method further includes performing an anneal process to form a barrier on the side walls of the hole, wherein the barrier has an oxide including Mn. The method further includes performing a CMP process.

### CROSS REFERENCE TO RELATED APPLICATIONS

This application is a continuation of PCT Application No. PCT/EP2008/058346, filed Jun. 29, 2008, which is hereby incorporated by reference in its entirety.

### BACKGROUND OF THE INVENTION

1. Field of the Invention

The present invention is related to the production of integrated circuits, in particular to the production of a copper contact in the transition between front end of line (FEOL) and back end of line (BEOL) stages of the production process.

2. Description of the Related Technology

Contacts between FEOL and BEOL are typically obtained by producing holes in the pre-metal dielectric (PMD) layer, e.g. SiO₂, and filling these holes with tungsten (W) metal. As contact dimensions shrink, replacing W by copper (Cu) is advantageous due to lower intrinsic resistivity of Cu metal. For both approaches (W and Cu) a metal barrier is required between the contact metal and silicided source/drain and gate areas, at the bottom of the hole. In the case of Cu this barrier is necessary to prevent the formation of harmful Cu-silicates. In order to control the resistance increase associated with the smaller contacting area, the barrier thickness has to be scaled down without compromising the reliability. Typically Cu barriers are deposited using physical vapor deposition (PVD)-based techniques which inherently deliver aspect-ratio dependent bottom & sidewall coverage thicknesses, which is limiting the scalability of PVD barriers. Prior art techniques include the use of ALD TaN, delivering a conformal barrier, which is however inefficient at preventing Cu-silicidation at very low thicknesses (2-3 nm), and tends to suffer from poor adhesion properties.

In conclusion, in order to use Cu in the contacts between FEOL and BEOL, a need exists in the prior art to provide a suitable barrier on the sidewalls and bottom of the contact hole, which on the one hand solves the problem of resistance increase due to the shrinkage in dimensions and on the other hand avoids the leakage of copper and hence the formation of copper silicides in and around the copper contact.

From Usui et al (IEEE Transactions on Electron Devices, vol. 53, n^{o} 10, October 2006), it is known to produce copper dual-damascene interconnects in the Back End of Line, by filling a via with a CuMn alloy by sputtering a CuMn seed layer on the side walls of the via, performing Cu deposition by electrochemical plating, annealing and removal of excess Cu by chemical mechanical polishing (CMP). During annealing, Mn reacts with SiO₂, resulting in the formation of MnSiₓO_{y}, on the sidewall of the hole, which acts as an effective barrier. This method cannot be used as a stand-alone option for Cu contacts since the technique would not provide a barrier on the metal silicide bottom of the contact hole.

The self-aligned deposition of CoWP on a source or drain region is known from Pan et al (2006 Symposium on VLSI Technology—1-4244-0005-8/06). According to this technique, it is possible to deposit CoWP selectively on silicided areas using an electroless metal deposition process. The goal of the CoWP layer onto the silicided source and drain areas is to decrease the series resistance and hence improve the electrical contact.

### SUMMARY OF CERTAIN INVENTIVE ASPECTS

Certain inventive aspects relate to a more effective and scalable way of producing a Cu contact between FEOL and BEOL.

One inventive aspect relates to a robust conductive barrier at the bottom of a Cu contact, the conductive barrier having at least a low contact resistance (preferably lower than in prior art) and the conductive barrier preventing Cu to react with silicide or Si.

One inventive aspect relates to a thin barrier (preferably thinner than in prior art) at the contact sidewalls, the thin(ner) barrier serving as a barrier to avoid leakage of Cu into the surrounding pre-metal dielectric (PMD).

One inventive aspect relates to a method for providing a suitable barrier layer into copper contact vias situated in the pre-metal dielectric (PMD) layer (e.g. SiO₂) of a semiconductor device.

One inventive aspect relates to a novel semiconductor device comprising copper contacts having a novel combination of barrier layer(s) on the bottom of the contact and on the sidewalls of the contact.

One inventive aspect relates to depositing a first selective barrier at the bottom of the via whereby the first barrier layer is preferably selected from a CoWP layer or a CoWB layer and depositing a second thin barrier layer onto the sidewalls of the via whereby the second barrier layer comprises an oxide comprising Mn. Hereafter the term ‘Mn-oxide’ is used to indicate an oxide comprising Mn and possibly other components, e.g. MnSiₓO_{y} with x between 0 and 100% and y higher than 0%.

The expression ‘between FEOL and BEOL’ is to be understood as follows: between source/drain and gate areas and a metal interconnect region (also called first metallization region) of an integrated circuit. Furthermore, a ‘barrier’ in the context of the present description is to be understood as a copper-barrier, i.e. a layer which inhibits the diffusion of Cu through the layer.

### BRIEF DESCRIPTION OF THE DRAWINGS

The drawing is intended to illustrate some aspects and embodiments of the present invention. Not all alternatives and options are shown and therefore the invention is not limited to the content of the attached drawing.

FIG. 1 shows a schematic view of a Cu contact produced according to one embodiment.

### DETAILED DESCRIPTION OF CERTAIN ILLUSTRATIVE EMBODIMENTS

The methods according to certain embodiments of the invention are scalable and fully compatible with existing semiconductor processing.

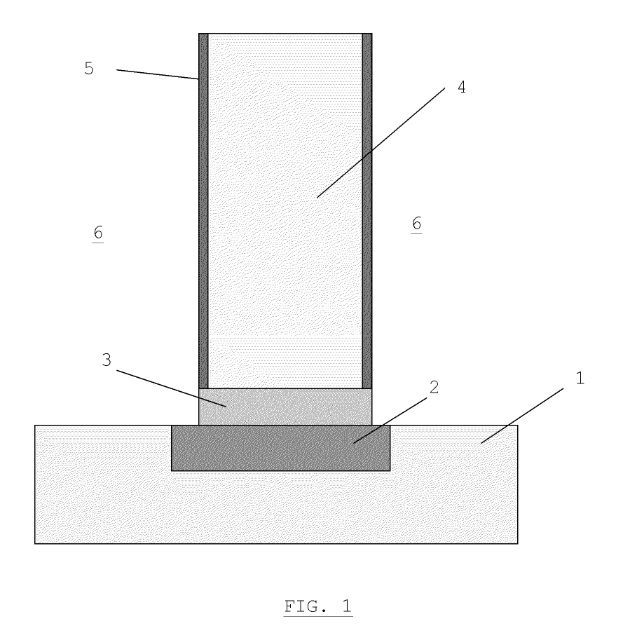

With reference to FIG. 1, one embodiment is related to a method for producing a contact through the pre-metal dielectric layer (6) of an integrated circuit, between the Front End of Line and the Back End of Line, wherein the PMD layer comprises oxygen, the method comprising:
producing a hole in the PMD,
depositing a conductive barrier layer (3) at the bottom of the hole,
depositing a CuMn alloy on the bottom and side walls of the hole,
filling the remaining portion of the hole with Cu,
performing an anneal process,
performing a chemical mechanical polishing (CMP) process.

The method is preferably performed on a substrate 1, e.g. a silicon substrate, having one or more silicided areas 2, typically nickel silicide areas (NiSi). These can be source/drain or gate areas of the integrated circuit. On top of the substrate is the pre-metal dielectric 6 which separates the gate and source/drain areas (FEOL) from the interconnect level(s) (BEOL) produced after the FEOL stage. The PMD can be a layer of SiO₂ or a CVD deposited low-k material, such as SiCO(H). An essential feature is that the PMD comprises oxygen.

The production of the hole in the PMD can be performed by any known technique. The conductive barrier layer 3 can be a CoWP layer or a CoWB layer.

A pre-treatment of the silicide is preferably performed. This can be a cleaning process. The pre-treatment may involve an HF-based activation of the NiSi by e.g. Pd atoms to initiate CoWP electroless deposition.

The deposition of the conductive barrier 3 at the bottom can be a selective electroless metal deposition process of any one of the following metals: CoWP, CoWB, CoWP(N), CoWB(N), wherein N is Nitrogen, being present in the grain boundaries of the CoWP or CoWB. According to one embodiment, this particular structure of CoWP(N) or CoWB(N) can be obtained by performing a plasma treatment in an atmosphere comprising NH₃ or N₂, i.e. with a plasma being generated from a gaseous mixture comprising at least nitrogen and/or NH₃, after depositing the barrier layer. The presence of N in the grain boundaries diminishes the diffusion of Cu through these boundaries (i.e. the presence of N avoids the fact that the grain boundaries act as diffusion paths for Cu).

A standard electroless CoWP (or CoWB) plating bath may be used with the typical process conditions inherent to a CoWP (or CoWB) deposition process in micro-electronics. In order to improve the selective electroless metal deposition process, the bottom of the contact hole (silicide) may be pre-treated, or in other words the bottom of the contact via is activated to improve the electroless process (e.g. performing a seeding process).

The thickness of the barrier layer 3 (e.g. CoWP or CoWB) is preferably in the range of 10 nm up to 100 nm, most preferably around 30 nm.

After depositing the barrier layer 3 at the bottom of the via, a pre-treatment process of the barrier layer is preferably performed, to clean the surface of the barrier layer, and specifically in order to substantially remove oxides from the surface of the barrier layer.

The deposition of the CuMn alloy can be performed by depositing a thin layer of CuMn alloy by PVD, for example an alloy comprising Cu and 2-8% Mn. The alloy may be deposited using the same PVD-based process and process conditions as for the subsequent deposition of a pure Cu seed layer which may be needed to perform electrochemical plating of copper to fill the copper contacts with copper.

The filling of the remaining gap with Cu 4 can take place by ECP (Electro-Chemical Plating). A standard acidic Cu plating bath may be used, as used in the microelectronics industry for interconnect fabrication.

The anneal process forms a Mn-Oxide layer 5 at the contact side wall, having a thickness of preferably around 3 nm (which is thinner than the known TaN barrier). The annealing process may be performed by a Furnace Thermal Anneal. The temperature and time period of this process depends on the particular alloy used and the nature of the dielectric onto which the barrier has to be formed. Typical temperatures are around 400° C. for 20-40 min. When the PMD layer comprises Silicon (e.g. PMD is SiO2), the oxide formed may be MnSiₓO_{y} with x between 0 and 100% and y higher than 0%. The self-formed Mn-Oxide diffusion barrier can only be formed at the contact sidewall. No Mn-Oxide will be formed at the contact bottom because there is no oxygen supply at the bottom of the contact hole (the PMD is giving the required oxygen through SiO₂).

The Mn-oxide (e.g. MnSiₓO_{y}) barrier at the sidewalls of the copper contact has a further advantage that it adheres very well to both the copper and the PMD (e.g. SiO₂), in contrast to state of the art barrier materials such as an ALD deposited TaN barrier layer.

The removal of excess Cu takes place by chemical mechanical polishing (CMP).

One embodiment introduces the novel use of CoWP or CoWB as a barrier material in cooperation with Cu, for the production of Cu contacts between FEOL and BEOL, the layer of CoWP or CoWB being applied at the bottom of a hole filled thereafter with the Cu contact.

One embodiment further introduces the novel combination of a CoWP or CoWB as a barrier material at the bottom of a copper contact with a self-forming Mn-oxide barrier layer at the sidewalls of the copper contact. Using this combination it is possible to avoid copper leakage out of the copper contact as well as a low contact resistance within the copper via.

One embodiment is related to a device comprising Cu contact vias through a pre-metal dielectric layer (PMD) comprising oxygen, the contact vias being between source/drain/gate areas 2 and a metal interconnect region, wherein a conductive barrier layer 3 is present at the bottom of the vias and a barrier layer 5 comprising an oxide comprising Mn is present at the sidewalls of the vias. According to the preferred embodiment, the conductive barrier layer comprises or consists of CoWP or CoWB, possibly with N being present in the grain boundaries of the CoWP or CoWB. Preferably, the PMD layer comprises Si (e.g. SiO₂) and the barrier layer on the side walls comprises MnSiₓO_{y} with x between 0 and 100% and y higher than 0%. The conductive barrier layer 3 preferably has a thickness of between 10 nm and 100 nm, most preferably around 30 nm.

One embodiment relates to the use of the novel combination of a CoWP or CoWB as a barrier material at the bottom of a copper contact with a self-forming Mn-oxide barrier layer at the sidewalls of the copper contact in the manufacturing process of a semiconductor device.

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention. The scope of the invention is indicated by the appended claims rather than by the foregoing description. All changes which come within the meaning and range of equivalency of the claims are to be embraced within their scope.

What is claimed is:

1. A method of producing a contact through a pre-metal dielectric (PMD) layer of an integrated circuit between front end of line and back end of line areas, wherein the PMD layer comprises oxygen, the method comprising:
producing a hole in the PMD layer;
depositing a conductive barrier layer at the bottom of the hole;
depositing a CuMn alloy on the bottom and side walls of the hole;
filling the remaining portion of the hole with Cu;
performing an anneal process to form a barrier on the side walls of the hole, the barrier comprising an oxide comprising Mn; and
performing a CMP process.

2. The method according to claim 1, wherein the conductive barrier layer is a CoWP layer or a CoWB layer.

3. The method according to claim 2, wherein the conductive barrier layer further comprises N in grain boundaries of the CoWP or CoWB.

4. The method according to claim 1, wherein the barrier layer is produced by electroless metal deposition.

5. The method according to claim 1, further comprising a plasma treatment process after the process of depositing the conductive barrier layer, to enhance the barrier properties of the layer.

6. The method according to claim 5, wherein the plasma treatment process takes place with a plasma being generated from a gaseous mixture comprising at least nitrogen and/or NH₃.

7. The method according to claim 1, wherein the PMD comprises Si and wherein the barrier comprises a layer of MnSiₓO_{y} with x between 0 and 100% and y higher than 0%.

8. The method according to claim 1, wherein the conductive barrier layer comprises copper.

9. The method according to claim 1, wherein the conductive barrier layer has a thickness between 10 nm and 100 nm.

10. The method according to claim 1, wherein the PMD layer is located between interconnect levels and one or more of the following: a gate, a source, or a drain area.

11. The method according to claim 1, wherein the gate, a source, or a drain area comprises silicide.

12. The method according to claim 1, wherein the CMP process removes excess Cu.

13. A semiconductor device manufactured by a process comprising the method according to claim 1.

14. A method of manufacturing process of a semiconductor device, the method comprising the method according to claim 1.

15. A semiconductor device comprising:
Cu contact vias through a pre-metal dielectric (PMD) layer, the layer comprising oxygen, the contact vias located between source/drain/gate areas and a metal interconnect region, wherein a conductive barrier layer is present at the bottom of the vias and wherein a barrier comprising an oxide comprising Mn is present at the sidewalls of the vias.

16. The device according to claim 15, wherein the conductive barrier layer comprises CoWP or CoWB.

17. The device according to claim 16, wherein the conductive barrier layer further comprises N in grain boundaries of the CoWP or CoWB.

18. The device according to claim 15, wherein the PMD layer comprises Si and wherein the barrier layer on the side walls comprises MnSiₓO_{y} with x between 0 and 100% and y higher than 0%.

19. The device according to claim 15, wherein the conductive barrier layer has a thickness between 10 nm and 100 nm.

20. The device according to claim 15, wherein the source, drain, or gate area comprises silicide.
